(19) United States
(12) Patent Application Publication
(10) Pub. No.: US 2013/0112274 A1
(43) Pub. Date: May 9, 2013

(54) Technique for fabrication of thin solar cells

(71) Applicant: Xiangcun Long, Albuquerque, NM (US)

(72) Inventor: Xiangcun Long, Albuquerque, NM (US)

(73) Assignee: QXWAVE INC, Albuquerque, NM (US)

(21) Appl. No.: 13/290,094

(22) Filed: Nov. 6, 2011

(51) Int. Cl. H01L 31/0264; H01L 29/02; H01L 29/16

(52) U.S. Cl. 136/261; 257/622; 257/635; 257/E29.082; 257/E29.002

(57) ABSTRACT

A low-cost fabrication technique, readily extensible to volume manufacturing is presented for thin strip solar cells. A wafer structure is disclosed for formation of thin strips. Plurality of strips is formed and mechanically supported by a thin layer of silicon with uneven surface. Processing methods are also disclosed to fabricate solar cells.

### FIELD OF THE INVENTION

This invention relates to a wafer structure and method to manufacture thin strip silicon solar cells.

### BACKGROUND OF THE INVENTION

Silicon materials are major parts of cost for silicon solar cells. It is an efficient way to reduce the cost of solar cells by using less silicon materials.

In US Patent “Semiconductor processing method for increasing usable surface area of a semiconductor wafer” (U.S. Pat. No. 7,595,543, Sep. 29, 2009), a number of ways were used to cut thin strips from semiconductor silicon wafers for increasing surface area to receive sun light. The most efficient way to form Si strips was wet anisotropic etching of (110) oriented Si wafers. A protective layer silicon nitride or silicon dioxide was deposited on (110) oriented Si wafers. Lithography processing and etching were used to form gratings windows on the wafers surface. The Si wafers were etched through in KOH solution at elevated temperatures. The width of the formed silicon strips is typically 1 mm and their thickness could be as thin as ten's microns while the length is over 10 centimeters. The silicon strips were supported by a protective frame. The silicon strips connected on protective frames can be further processed for fabrication of solar cells and assembling as solar cell modules. The effective area of solar cells for absorption of solar light was greatly increased and much less expensive silicon materials were used. However, the wafer structures and processing method for cutting thin silicon strips and fabrications remain numbers of technical challenges. Firstly, the silicon wafers can not be uniformly etched through on whole wafer area. The depth variation of etched deep grooves ranges up to hundreds microns for 1-mm thick wafers. It is difficult to process the uneven structures of etched silicon strips for fabrication of solar cells. Secondly, the elongate thin silicon strips are easily adhered together each other. It is very difficult to uniformly diffuse dopant chemical elements into adhered silicon strips. The properties and performance of solar cells were seriously affected by non-uniform diffusions for fabrication of p-n junctions. More seriously, it is very hard to separate the adhered silicon strips for following assembling. The processing cost was increased although the adhesion of silicon strips may be removed by fabrication of interconnecting portions connecting adjoining strips on rear side of silicon wafers. Thirdly, a frame comprising the periphery of the semiconductor wafer was used to connect and mechanically support each strip. The thickness of the frame is the same as the one of the wafer and the width is typically 5 mm The considerable amount of silicon materials was used to form the frame which is useless for fabrication of solar cells. Further, there exists an overlap region for p-type and n-type semiconductors to form a p-n junction as a solar cell. Carriers heavily compensate on the overlap region. Significant loss was induced and fill factor of cells was reduced because of the minor carrier recompensation on the overlap region. Finally, photolithography has to be used for processing to define patterns. The cost for fabrications of solar cells was greatly increased.

It is an objective of present invention to disclose a semiconductor wafer structures for fabrication of solar cells.

Another object of the present invention is that a processing method is disclosed to form planar layers on uneven surface and structure of trenches for wafers as protective and sacrificial film layers for etching of semiconductor materials and selective deposition metal film layers.

It is a further object of present invention that new thin solar cells provide efficient, inexpensive and convenient solution to electric power generation applications.

### SUMMARY OF THE INVENTION

According to the invention, deep trenches are formed on semiconductor wafers. The wafers are partially etched and the bottom surfaces of grooves are uneven. Plurality of strips is formed on the wafers. The remained thin layer of wafer materials mechanically support and connects adjoining strips.

Another embodiment of present invention is that thin film layers of materials such as polymer, wax or dielectric oxide are sintered on bottom surfaces of trenches. The layers of films are formed by filling of solutions on the trenches followed with evaporation drying.

Another embodiment of present invention is that nanometers structures are fabricated on the surfaces of strips. In this manner, reflection of lights is greatly reduced on the surface of strips.

Present invention also disclosed a method to separate p-type and n-type semiconductors from conductive electrodes with high spatial resolution.

Present invention also disclosed a method to form nickel silicide as conductive electrodes of solar cells.

### BRIEF DESCRIPTION OF THE DRAWINGS

A better understanding of the invention will obtained by reference to the detailed description below, in conjunction with the following drawings, in which:

FIG. 1 shows top and cross-sectional side views of etched wafer structures.

FIG. 2 shows top view of rear surface of etched wafer structure.

FIG. 3 shows cross-sectional side view of wafer structure with diffused layer and nanometer surface layer. FIG. 3a shows cross-sectional side view of detail nanometer structure and oxide layer. FIG. 3b shows top view of surface nanometer structure on wafers.

FIG. 4 shows cross-sectional side views of wafer structure with metal electrode layer on top of strips

FIG. 5 shows cross-sectional side views of wafer structure with first film on the bottom of trenches.

FIG. 6 shows cross-sectional side views of wafer structure with first film and second film on the bottom of trenches.

FIG. 7 shows cross-sectional side views of wafer structure with first film and second film on the bottom of trenches and filled materials on the top of trenches.

FIG. 8 shows cross-sectional side views of wafer structure after the silicon on the bottom of wafer is etched away.

FIG. 9 shows cross-sectional side views of wafer structure with metal layer as second electrode for solar cells

FIG. 10 shows cross-sectional side views of thin solar cells.

### DETAILED DESCRIPTION OF THE INVENTION

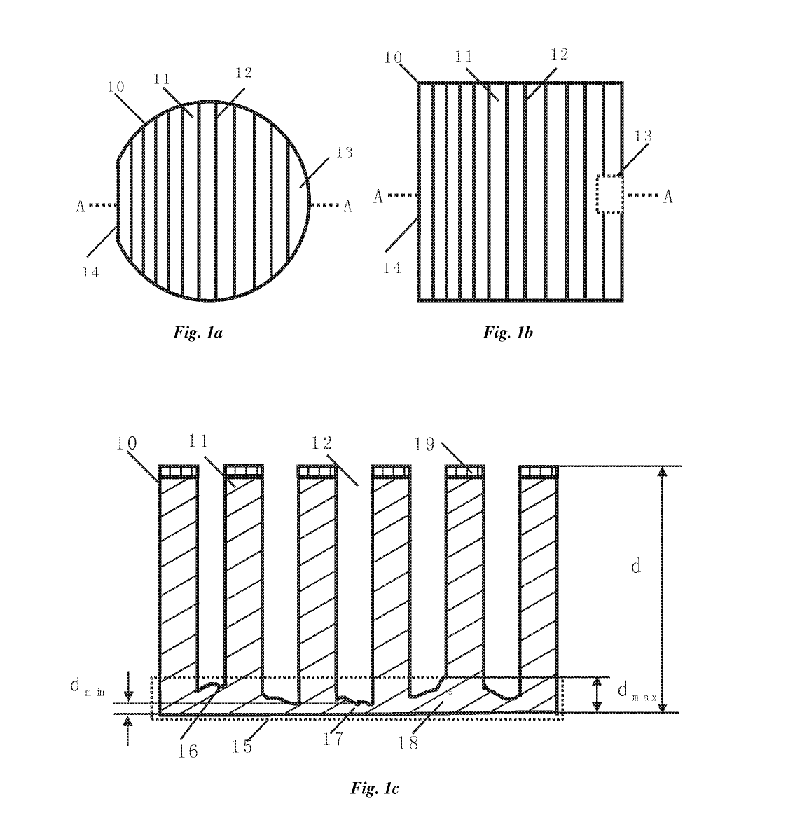

(110) oriented single crystalline Si wafers 10 are used. The wafer 10 can be circle shape as shown in FIG. 1a or square shape as shown in FIG. 1b. Front surface of the wafer is mirror polished. An etching protect mask is fabricated on the front surface of side Si wafer. The lines of etching protect mask are precisely aligned to the marker line 14 of (111) direction of the Si crystal. An unetched Si pad area 13 is remained for handling of the said Si wafer for further processing. The typical size of said Si pad range from 5 mm×5 mm to 10 mm×10 mm. The thickness of the said pad is same as the one of the wafers. The said Si wafer is etched through open windows of the mask by KOH solution at elevated temperature. A cross sectional view along line A-A of silicon wafers is shown in FIG. 1c. Deep trenches 12 and strips 11 are formed on Si wafer 10 as shown in FIG. 1c. The dotted line 15 indicated uneven structures of unetched Si materials with said trenches and said strips close to the rear surface of the said wafers. The surfaces 16 of said trenches are usually uneven on whole wafer area since etching rate is varied across the whole Si wafer. The variations of etching rate are due to formation of hydrogen bubbles and depletion of KOH etching solution during chemical reactions. The thickness of unetched thinnest Si wafer 17 is dₘᵢₙ. while the thickness of unetched thickest Si wafer 18 is dₘₐₓ. The difference between the thickness dₘᵢₙ of unetched thinnest Si wafer 17 and the thickness dₘₐₓ of unetched thickest Si wafer 18 could be over 100 microns for 1-mm thick Si wafers. The thickness dₘᵢₙ of unetched thinnest Si wafer 17 can be adjusted by variations of etching time. Typically, the value of the thickness dₘᵢₙ of unetched thinnest Si wafer 17 ranged from zero to 200 microns. FIG. 2 is an image of scanning electron microscope which shows the top view of the rear surface 20 of etched Si wafer 10. A network of Si materials is formed on rear surface 20 of said etched Si wafers. The adjoining strips 11 are mechanically connected by the unetched Si materials 21. The trenches 12 is located on positions where Si materials were etched away and the thickness dₘᵢₙ of unetched thinnest Si wafer is zero.

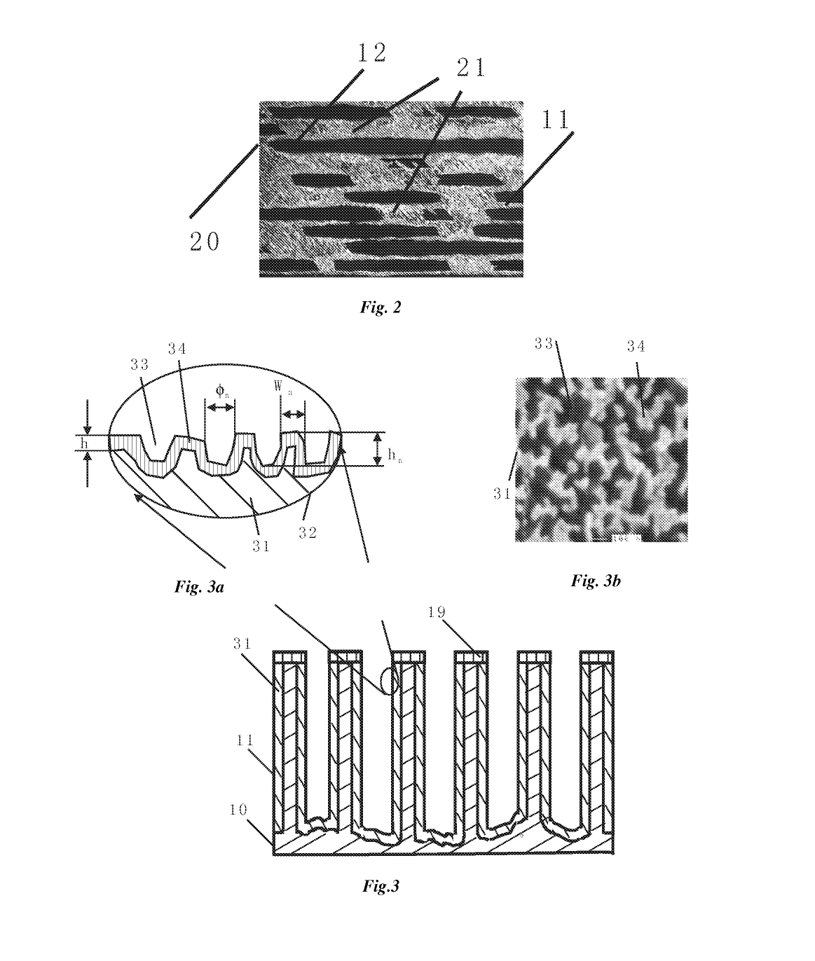

In accordance with the invention, referring to FIGS. 3-10, following processes are necessary to fabricate solar cells.

Reflectivity of bare optical smooth silicon surfaces in air is ˜34% at solar wavelength. The high reflection greatly reduced energy conversion efficiency of solar cells. The surface of strips 11 are textured with nanometers structure as an antireflection layer (ARC). The amplified nanometers structured antireflection layer (ARC) 32 is shown in FIG. 3a. The reflectivity of the textured Si surface with said ARC layer on said strips is reduced to less than 5% for solar wavelength. The said ARC layer is formed by metal-assisted chemical etching technique. The said etched wafers are immersed in a metallization aqueous solution containing 0.14 M HF and 5×10⁻⁴ M AgNO₃ for 5 seconds. Ag nanoparticles were deposited on said wafers. After rinsed in DI water, the said wafers are immersed in HF/H₂O₂/H₂O solution for 60 second or so. The Ag nanoparticles were removed away by dipping the said wafers into HNO₃ solution followed with DI water rinsing. The characteristic size, φₙ, as shown in FIG. 3a, of formed nanopores 33 is less than 100 nm The thickness wₙ of walls for said nanopore is also less than 100 nm The height hₙ of the said nanopore is less than 300 nm The top view of said nanopores is shown in FIG. 3b, an image of scanning electron microscope. After drying, the said wafers are diffused with a dopant to change polarity of said Si wafers. The dopant is typically phosphorus for p-type silicon wafers while boron is used as a dopant for n-type silicon wafers. The thickness of diffusion layer 31 is not less than 1 micron. After formation of said diffused layer, the said silicon wafers are heated up to temperature of 560° C. for over ten minutes. A thin layer 34 of silicon dioxide is formed on said diffused layer. The thickness, h, as shown in FIG. 3a, of said oxide layer is typically 10 nm The said oxide layer is used to passivate the silicon crystal to reduced surface defects. Addition layer of Si₃N₄ may be deposited on the said oxide layer both for further reducing reflection of sun light and enhancement of passivity for silicon surfaces. The structure of formed wafers is shown in FIG. 3. The diffused semiconductor layer 31 has opposite semiconductor polarity with initial started strips material 11 to form p-n junctions.

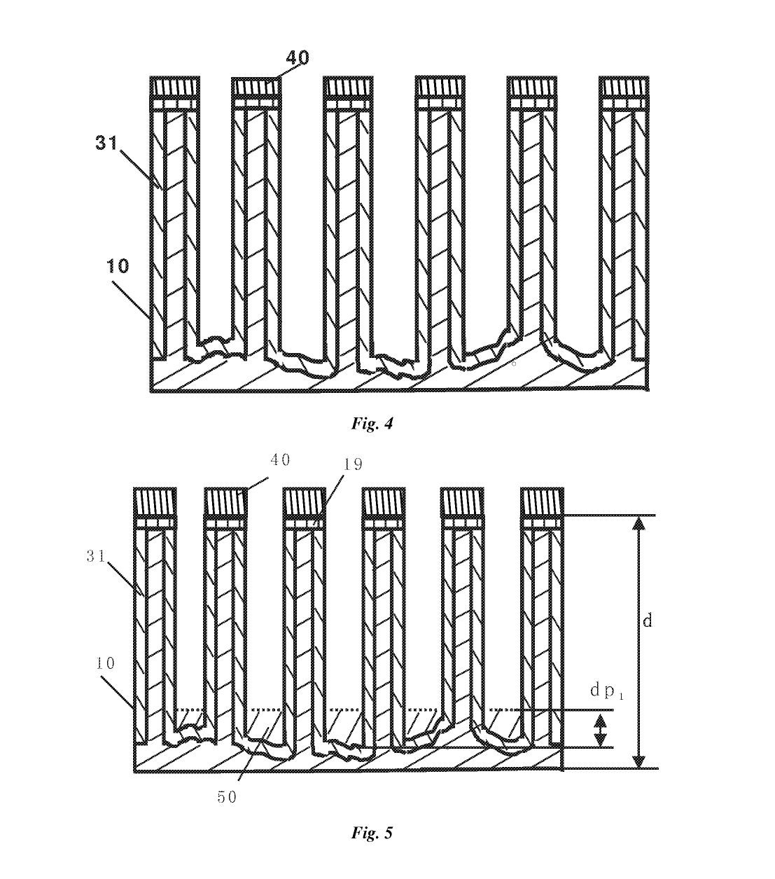

A layer of metal nickel was selectively deposited on top of said silicon strips. The said silicon wafers deposited with metal Ni was heated up on 400° C. for 30 minutes. Part of nickel penetrated through said oxide layer into silicon. A layer of nickel silicide was formed on said silicon strips to reduce contact resistances. The metal nickel and nickel silicide 40 was used as one of electrodes for solar cells, as shown in FIG. 4.

Multi-layers of films were deposited on the bottom of said trenches for fabrication of solar cells. The first layer of film 50 was deposited on the bottom of said trenches to flat the uneven bottom surfaces of the trenches, as shown in FIG. 5. The deposition of said film can be implemented by fully filling of a solution into trenches followed with drying by evaporation. A solution containing the material of film 50 is dropped into said trenches until its level is same as the one of top surface of said wafers. The solvent of said solution is slowly dried when said wafers are heated to a suitable temperature. The material sinters on the bottom of said trenches after the solvent is evaporated. The thickness of film 50 was dp₁. The thickness of said wafers was d. The thickness of unetched thickest Si on said wafers is dₘₐₓ. Typically, the thickness of said wafers, d, is much grater than the thickness dp₁ of said film on said wafers. The concentration ρ₁ of said solution is approximately:

$${ρ}_{1} \approx \frac{{dp}_{1}}{d - {d}_{max}} \qquad ( 1 )$$

The material for film 50 is beeswax with low melting temperature Tₘ˜62° C. The wax on the bottom of said trenches can be heated up to melting temperature to reflow for further leveling and smoothing of the said film.

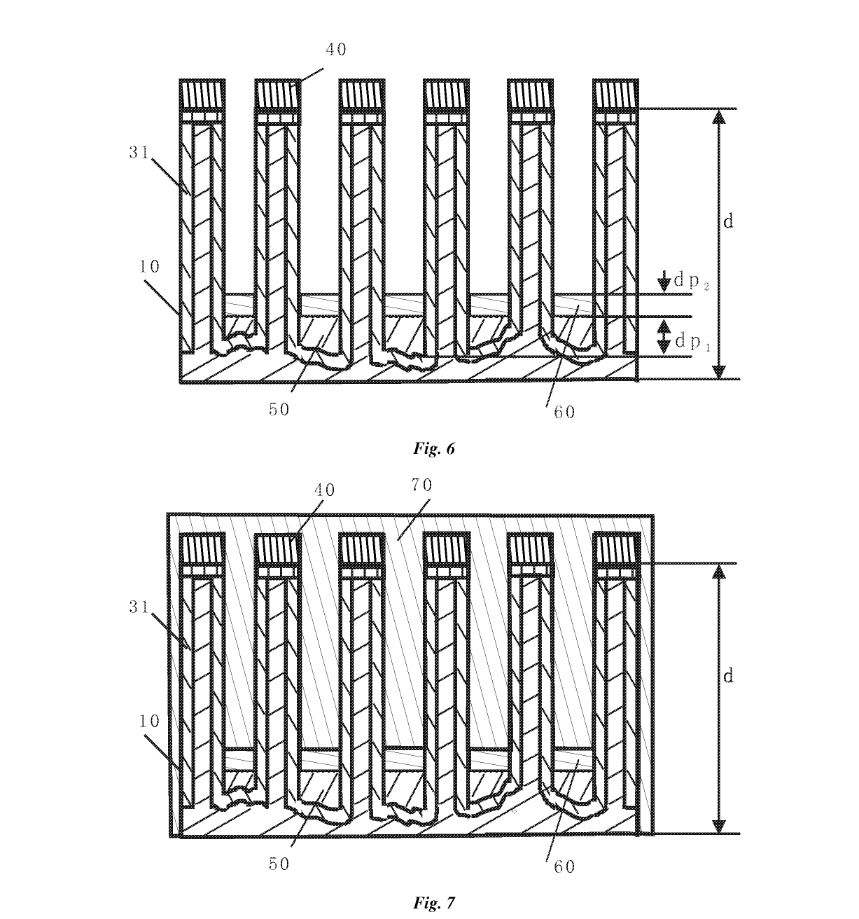

The second layer of film 60 in FIG. 6 was used as a sacrificial layer for deposition of metal film. The layer of film 60 can be formed in same way as above. A solution fully fills up the trenches followed by drying with evaporation. The thickness of film 60 is dp₂. The concentration ρ₂ of the solution is approximately:

$${ρ}_{2} \approx \frac{{dp}_{2}}{d - {d}_{max}} \qquad ( 2 )$$

The preferred material for film 60 is styrene-isoprene-styrene block copolymer. The typical solvent of styrene-isoprene-styrene block copolymer is toluene.

Afterwards, the trenches and front surface of said wafers was covered with a polymer 70 as shown in FIG. 7. A preferred material for polymer 70 is carnauba wax with higher melting temperature of Tₘ˜82° C.

Usually, a dopant such as boron or phosphor is diffused into silicon to change polarity of semiconductor materials for formation of p-n junction at high temperature over 900° C. A protective dielectric film is often coated on the area of silicon material for selectively doping. However, it is very difficult to diffuse the dopant into semiconductor material with high spatial resolution at such high temperature. The adjacent area of silicon material coated with a protective dielectric film near the diffusion source is often diffused with the dopant on some extent. This effect greatly reduces the open circuit voltage of the formed p-n junction. Doping semiconductor with high spatial resolution is essential for formation of a p-n junction since the physical size of the strips is often limited. The spatial sharpness of p-type and n-type silicon material is implemented by etching away the diffused layer at room temperature as released on present invention, as discussed in following section. Further, metal electrode of p-type semiconductor should be not connected with electrode of n-type semiconductor or n-type semiconductor itself. Otherwise, shunt paths will exist and performance of solar cell will be degraded. Selective deposition of metal electrode films is often implemented by photolithography processing technique. This will greatly increase fabrication cost of the solar cells. A sacrificial layer is used to eliminate the shunt path of electrodes in present invention. The process is much simpler than the ones used in lithography processes. Fabrication cost is greatly reduced.

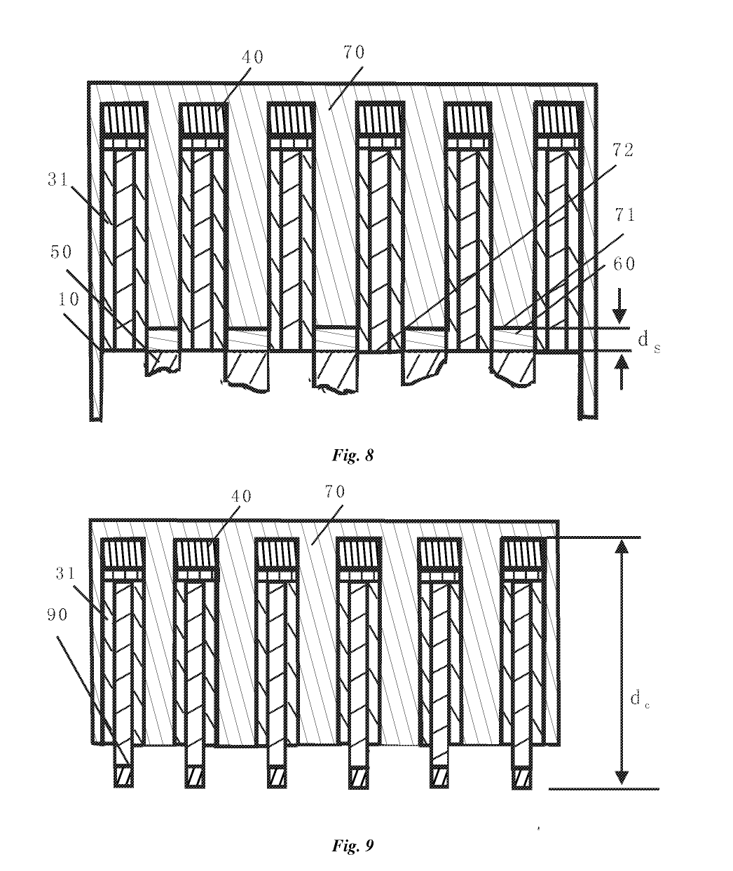

The said wafer with protected front surfaces is immersed in a solution for etching away the silicon near the rear surface. The solution of etching silicon is mixed HF (5 wt. %):HNO₃ (95 wt. %). Exposed silicon is etched away at room temperature. The etching is stopped when the surface 72 of silicon is from the surface 71 of material 70 with distance dₛ, as shown in FIG. 8. The metal nickel film is deposited. After removing film 60 and etching away exposed parts of diffused layer 31 while most of other part of diffused layer 31 was covered and protected by film 70, nickel film 90 is selectively deposited on the silicon, as shown in FIG. 9. The electrode 90 separate from diffused layer 31 with a distance dₛ. The distance dₛ ranges from 5 microns to 300 microns for electrically isolation of electrode 90 from diffused layer 31.

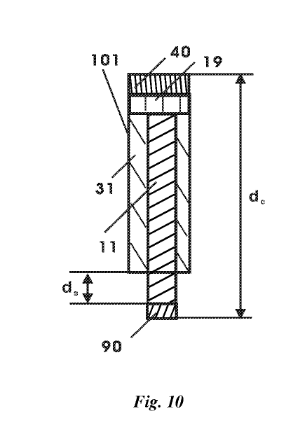

The cross section view of formed single strip solar cell is shown in FIG. 10. The solar cell 101 has metal electrode 40 and 90. The diffused layer 31 with nanometer structure antireflection layer wraps most part of strip 11 and separates from electrode 90 with distance dₛ.

What is claimed is:

1. A monocrystalline silicon semiconductor wafer comprising a plurality of strips, trenches, a thin bottom rear layer and a thick pad fabricated from a single semiconductor substrate, wherein the adjacent strips are mechanically interconnected and supported by said thin bottom rear layer.

2. A monocrystalline silicon semiconductor wafer in claim 1, wherein said bottom rear layer has uneven surfaces and thickness dₘᵢₙ of thinnest unetched silicon on said bottom rear layer ranges from zero to 200 microns.

3. A monocrystalline silicon semiconductor wafer in claim 1, wherein the surface size of said pad ranges from 5 mm×5 mm to 10 mm×10 mm while thickness of the said pad is the same as the one of said wafer.

4. A monocrystalline silicon semiconductor wafer in claim 1, wherein nanometers layer with holes and walls are formed on the surface of said strips, the characteristic size of both said holes and walls are less than 100 nm, the thickness of the said nanometers layer is less than 300 nm.

5. A monocrystalline silicon semiconductor wafer in claim 4, wherein the surface of said strips diffused with a dopant including boron or phosphordus is covered with a thin oxide layer with less than 10-nm thickness.

6. A monocrystalline silicon semiconductor wafer in claim 6, wherein metal layer including nickel is selectively deposed on the top surface of said strips.

7. A monocrystalline silicon semiconductor wafer in claim 6 wherein metal nickel layer is heating up to 400° C. for 30 minutes to form nickel silicide

8. A monocrystalline silicon semiconductor wafer in claim 7, wherein two layers of thin films, first layer and second layer, are formed on the bottom of said trenches.

9. The said ith (i=1,2) thin film in claim 8 formed by solution-filling up and dried by evaporation at elevated temperature.

10. The concentration ρᵢ of the said solution for said ith (i=1,2) layer of film in claim 9 determined by ρᵢ≈dpᵢ/(d−dₘₐₓ), wherein dpᵢ is the thickness of said ith layer of film, d is the thickness of the said wafer.

11. The said first thin film in claim 9 reflowed for smooth and leveling of the surface of said film on the bottom of said trenches by heating up to melting temperature of film materials.

12. The said first film in claim 9 comprised of beeswax with low melting temperature ˜62° C.

13. The said second thin film in claim 9 comprised of styrene-isoprene-styrene block copolymer.

14. A monocrystalline silicon semiconductor wafer in claim 9, wherein a layer of material fully filling up the trenches with said two layers of thin films works as a protective coating layer and mechanically connects structure for said strips.

15. The said filling up material in claim 14 comprised of carnauba wax with higher melting temperature ˜82° C.

16. A monocrystalline silicon semiconductor wafer in claim 15, wherein the said thin rear bottom Si layer is etched away.

17. A solar cell in claim 16, wherein a layer of metal film is selectively deposited on the rear surface of said strips.

18. A solar cell in claim 16, wherein the part of said diffused layer with width of dₛ is etched away at room temperature.

19. The width of said etched diffused layer, dₛ in claim 16, ranges from 5 microns to 300 microns.

20. A solar cell in claim 19, wherein the said metal film separates from the said diffused layer with a distance dₛ.
